(19) United States
(12) Patent Application Publication
(10) Pub. No.: US 2004/0084208 A1
(43) Pub. Date: May 6, 2004

(54) Article and method for reducing external excitation of MEMS devices

(76) Inventors: Thomas W. Ives, Boise, ID (US); Donald J. Fasen, Boise, ID (US); Curt N. Van Lydegraf, Eagle, ID (US)

Correspondence Address: HEWLETT-PACKARD COMPANY, Intellectual Property Administration, P. O. Box 272400, Fort Collins, CO, 80527-2400, US

(21) Appl. No.: 10/283,560

(22) Filed: Oct. 30, 2002

(51) Int. Cl. H05K 7/06

(52) U.S. Cl. 174/260

(57) ABSTRACT

A printed circuit assembly comprises a printed circuit board and a micro-electro-mechanical system on the printed circuit board. At least one motion damping member is positioned between the printed circuit board and the micro-electro-mechanical system.

### THE FIELD OF THE INVENTION

The present invention generally relates to micro-electro-mechanical systems (MEMS), and more particularly to articles and methods for reducing the amount of external mechanical excitation transmitted to MEMS devices.

### BACKGROUND OF THE INVENTION

Many types of micro-electro-mechanical systems (MEMS) are known in the art, and such systems are used or may be used in a wide variety of applications. MEMS devices offer numerous advantages, such as small size and relatively low cost, which are conducive to using MEMS devices in applications which have space constraints. For example, MEMS devices may be used as part of a larger data storage system, allowing greater amounts of data to be stored in a fixed space; or MEMS devices may be used in small and/or portable systems such as cell phones or personal digital assistants (PDAs) to enable those systems to have greater functionality.

For example, an Atomic Resolution Storage (ARS) device that uses MEMS is described in U.S. Pat. No. 5,557,596 to Gibson et al. The storage device of Gibson et al. uses a movable rotor having a storage medium. The rotor and storage medium thereon are moved by micro actuators about a plane, so that data may be written to and read from various locations on the storage medium. To assure that the storage medium is accurately written to and read from as it is moved by the micro actuators, movement of the rotor and storage medium must be very accurately controlled.

Although MEMS devices offer numerous advantages, the operation of many MEMS devices are unfavorably susceptible to external excitation (e.g., vibration). Specifically, because MEMS devices typically included movable elements as part of their system, mechanical excitation from an external source may cause those movable elements to move in an undesired manner. Whether used in portable devices or in non-portable devices, the MEMS device will often be subjected to external mechanical excitation from any number of sources (such as while being carried by a person or in a vehicle, or from other machinery in a building). In the example of the storage device of Gibson et al., the external mechanical excitation (vibration) may be transmitted to the MEMS device, and cause undesired and uncontrolled movement of the rotor and storage medium thereon. The undesired movement may adversely effect the operation of the device, leading to errors in writing and/or reading data in the device.

Although the example given here relates to a MEMS device which is used in a data storage system, similar problems are associated with external mechanical excitation of other types of MEMS devices.

### SUMMARY OF THE INVENTION

A device and method which reduces or eliminates the influence of external excitation on micro-electro-mechanical system devices is described. In one embodiment according to the invention, a printed circuit assembly comprises a printed circuit board and a micro-electro-mechanical system on the printed circuit board. At least one motion damping member is positioned between the printed circuit board and the micro-electro-mechanical system.

### BRIEF DESCRIPTION OF THE DRAWINGS

FIG. 1 is a top view of MEMS devices on an embodiment of a printed circuit assembly having external excitation reduction means according to the invention.

FIG. 2A is an enlarged view of a portion of the printed circuit assembly of FIG. 1 showing one embodiment of external excitation reduction means according to the invention.

FIGS. 2B and 2C are enlarged views of alternate embodiments of external excitation reduction means according to the invention.

FIG. 3 is a top view of a MEMS device on another embodiment of a printed circuit assembly having external excitation reduction means according to the invention.

FIG. 4 is an enlarged perspective view of a portion of the printed circuit assembly of FIG. 3.

FIG. 5 is a perspective view of MEMS devices on another embodiment of a printed circuit assembly having external excitation reduction means according to the invention.

FIG. 6 is a top view of a MEMS device on yet another embodiment of a printed circuit assembly having external excitation reduction means according to the invention.

### DETAILED DESCRIPTION

In the following detailed description of the preferred embodiments, reference is made to the accompanying drawings which form a part hereof, and in which like numerals are used for like and corresponding parts of the various drawings.

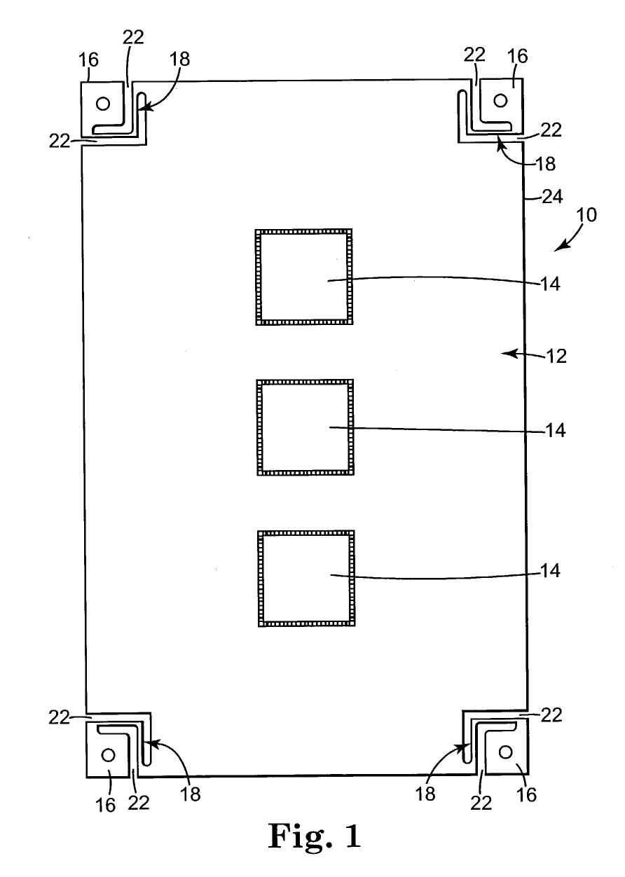

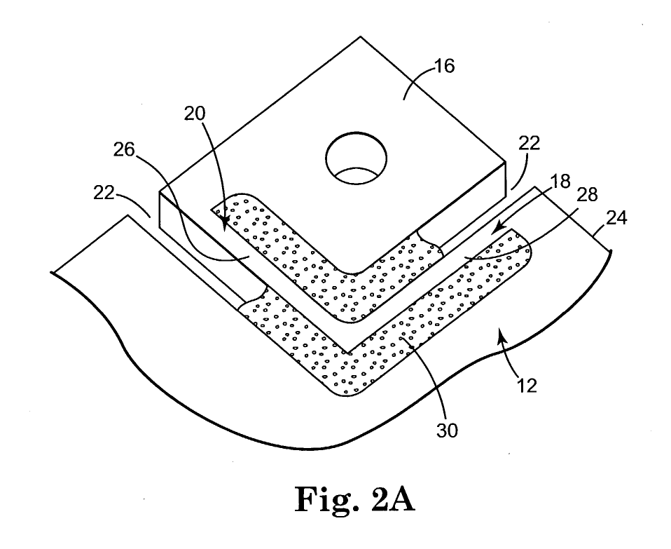

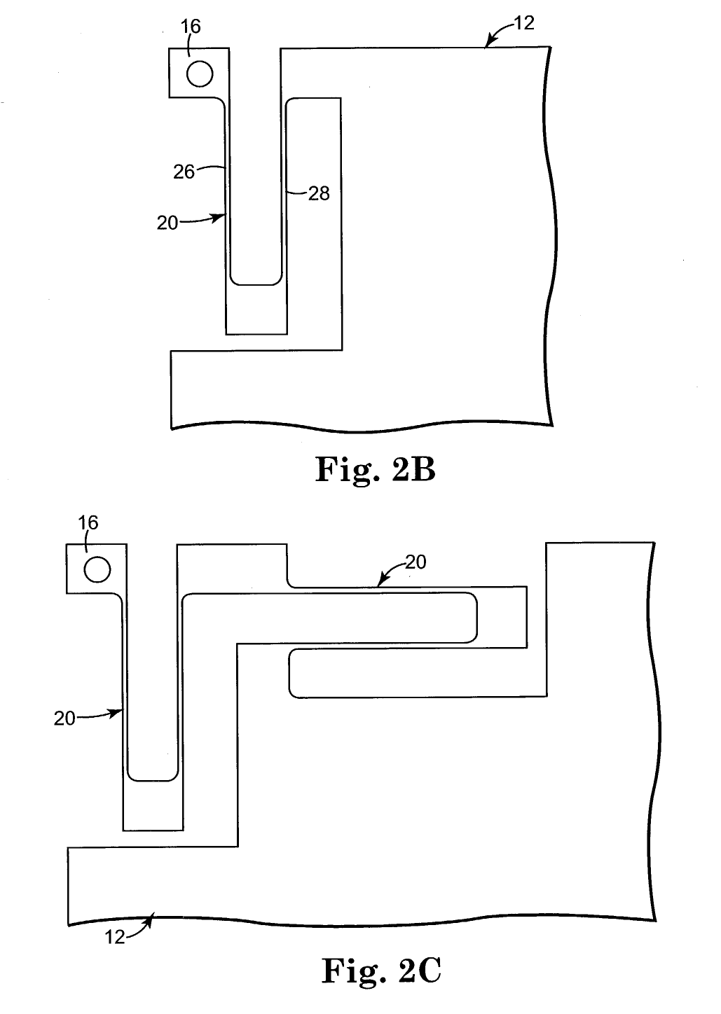

An embodiment of a printed circuit assembly 10 which reduces or eliminates the effect of external mechanical excitation according to the invention is shown in FIGS. 1 and 2A. Printed circuit assembly 10 includes a printed circuit board 12 and a plurality of MEMS devices 14 positioned on printed circuit board 12. Although three MEMS devices 14 are shown in FIG. 1, any chosen number of MEMS devices 14 may be used. A portion of printed circuit board 12 is shaped to define a plurality of mounting portions 16 for connecting the printed circuit board 12 to a frame (not shown). A flexible vibration damping member 18 is positioned between each of the mounting portions 16 and body of the printed circuit board 12. Flexible members 18 provide a vibration damping suspension for MEMS devices 14, such that the transmission of external mechanical excitations from the mounting portions 16 to the MEMS device 14 is reduced or eliminated.

As shown in FIGS. 1 and 2A, the vibration damping member 18 comprises an elongated flexure (also referred to herein as a beam) 20 which extends between the mounting portions 16 and the body of the printed circuit board 12. The body of the printed circuit board 12, mounting portions 16, and elongated flexures 20 are integrally formed so as to provide a monolithic structure. Mounting portions 16 and elongated flexures 20 may be formed by ablating slots 22 into the printed circuit board 12. In one embodiment according to the invention, a plurality of slots 22 extend into the printed circuit board 12 from the edges or periphery 24 of printed circuit board 12, wherein pairs of the plurality of slots 22 are positioned and shaped to define the desired profile of mounting portions 16 and elongated flexures 20 therebetween. The terms “ablating” and “ablation” as used herein refer to the removal of material by any means, including but not limited to cutting, abrading, routing, etching or evaporating.

As shown in FIGS. 1 and 2A, printed circuit board 12 is rectangular in shape, and mounting portions 16 are positioned adjacent to the periphery of printed circuit board 12, and in particular at each corner of the printed circuit board 12. However, mounting portions 16 and their associated flexures 20 may be placed in alternate positions on printed circuit board 12, and may even be placed toward the center of printed circuit board 12 if desired. Similarly, in FIGS. 1 and 2A, flexures 20 are each shown to include a first leg 26 and a second leg 28 which are substantially perpendicular to each other. However, as illustrated in FIGS. 2B and 2C, flexures 20 may have any number of legs and may have a myriad of other shapes and orientations, depending upon the desired effect.

As noted above, mounting portions 16 and elongated flexures 20 may have many desired shapes, positions and orientations. The shape, position and orientation of mounting portions 16 and flexures 20 will be dictated by the intended use of the device and the mechanical characteristics suitable to prevent or reduce the adverse effects of external vibrations. Many possible flexure dimensions and architectures may be created to obtain the desired mechanical characteristics (such as resiliency and damping characteristics), and the final characteristics will depend upon the MEMS devices being used. The mechanical characteristics may be determined, for example, through modeling and measurement techniques well-known in the art. The resiliency and damping characteristics of the flexures 20 may be “tuned” to avoid or reduce transmission of a particular frequency or range of frequencies of vibration. The “tuning” to be accomplished, for example, by altering the dimensions of flexures 20, or by changing the mass of the printed circuit assembly 10. To further tune the system and aid the damping ability of flexures 20, a mechanically-dissipative material 30 (such as foam) may be coupled between the flexures 20 and at least one of the body of printed circuit board 12 and the mounting portions 16. For example, as illustrated in FIG. 2A, slots 22 may be filled (either in part or completely) with mechanically-dissipative material 30.

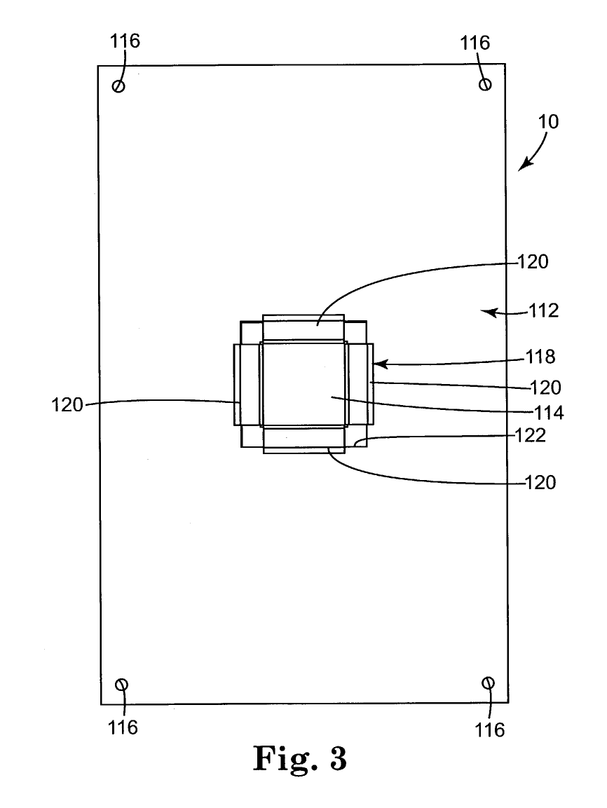

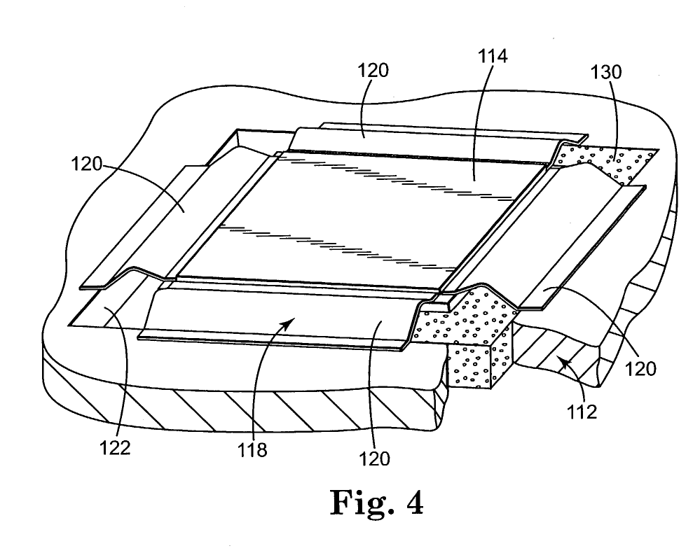

Another embodiment of a printed circuit assembly 10 which reduces or eliminates the effect of external mechanical excitation on a MEMS device is shown in FIGS. 3 and 4. The embodiment of FIGS. 3 and 4 mechanically isolates the MEMS device itself, rather than isolating the entire printed circuit assembly-as shown in FIGS. 1 and 2. In FIGS. 3 and 4, printed circuit assembly 10 includes a printed circuit board 112 and a MEMS device 114 positioned on printed circuit board 112. Although only a single MEMS device 114 is shown in FIGS. 3 and 4, additional MEMS devices 114 may be used, as will be discussed below. Corners of printed circuit board 112 include mounting portions 116 for connecting the printed circuit board 112 to a frame (not shown). A flexible vibration damping member 118 is positioned between the printed circuit board 112 and the MEMS device 114. Flexible member 118 provides a vibration damping suspension for MEMS devices 114, such that the transmission of external mechanical excitations the MEMS device 114 is reduced or eliminated.

As shown in FIGS. 3 and 4, the vibration damping member 118 comprises a flexible circuit 120 which extends between the body of the printed circuit board 112 and MEMS device 114. The body of the printed circuit board 112 includes a cavity or opening 122 of a size sufficient to receive MEMS device 114. The MEMS device 114 is suspended within cavity 122 by one or more flexible circuits 120. At least one flexible circuit 120 provides electrical connection between the MEMS device 114 and printed circuit board 112.

As can be seen in FIG. 4, flexible circuits 120 are oriented such that they are flexed or buckled when supporting MEMS device 114. The flexible circuits 120 are buckled or flexed to provide the desired amount of mechanical resiliency and damping. The amount of buckling or flexing and the dimensions of the flexible circuit 120 will be dependent upon the intended use of the MEMS device 114 and the mechanical characteristics (such as resiliency and damping characteristics) suitable to prevent or reduce the adverse effects of external vibrations. The mechanical characteristics may be determined, for example, through modeling and measurement techniques well-known in the art. The resiliency and damping characteristics of the flexible circuits 120 may be “tuned” to avoid or reduce transmission of a particular frequency or range of frequencies of vibration. The “tuning” to be accomplished, for example, by altering the dimensions of flexible circuits 120, or by changing the mass of the printed circuit assembly 10. To further tune the system and aid the damping ability of flexible circuits 120, cavity 122 may be filled (either in part or completely) with a mechanically-dissipative material 130 (such as foam), as illustrated in FIG. 4.

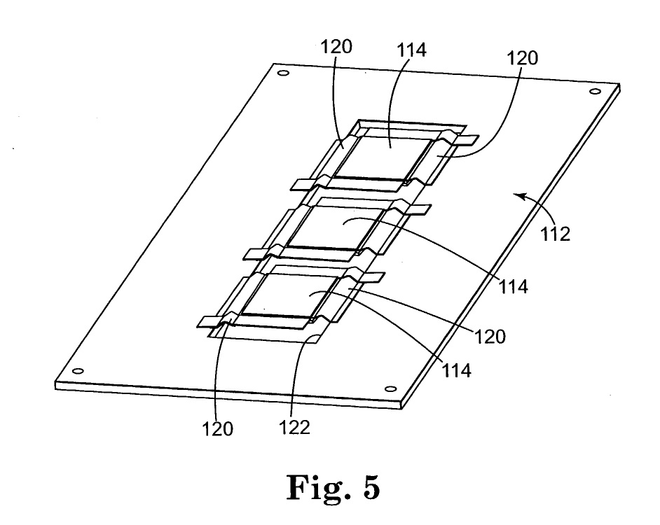

Although only a single MEMS device 114 is shown in FIGS. 3 and 4, printed circuit board 112 may be provided with a plurality of cavities 122, with a MEMS device 114 positioned within each cavity 122 in a manner described above. Alternately, a plurality of MEMS devices 114 may be suspended within a single cavity 122, as shown in FIG. 5. In the embodiment of FIG. 5, each MEMS device is supported by two flexible circuits 120.

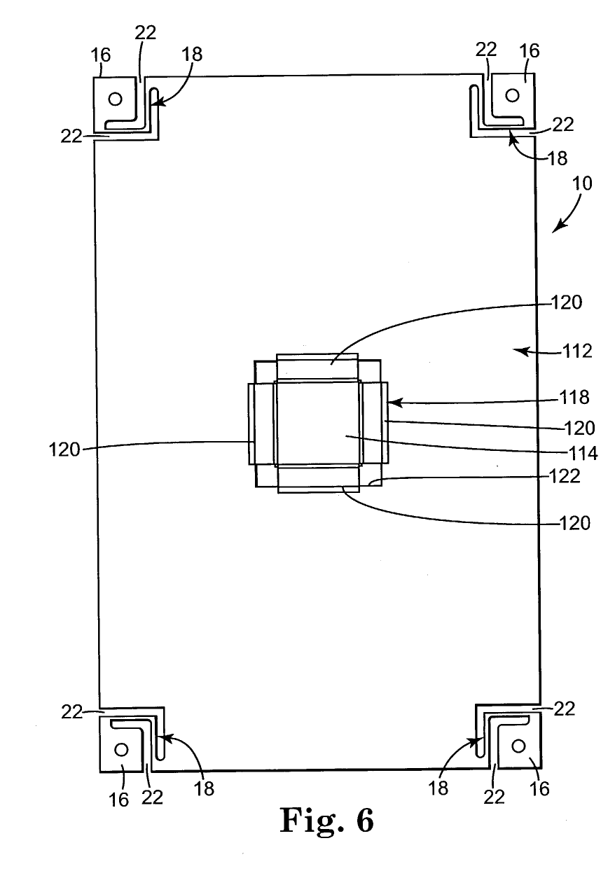

In yet another embodiment illustrated in FIG. 6, a printed circuit assembly 10 may be provided with a vibration damping suspension comprised of both elongated flexures 20 and flexible circuits 120. In this embodiment, the MEMS device is mounted in a region of the printed circuit board that is substantially isolated from the rest of the printed circuit assembly by use of elongated flexures 20, such as those shown in FIGS. 1 and 2A. The MEMS device is suspended on and electrically connected to the printed circuit board using flexible circuits as shown in FIGS. 3-5. This embodiment is beneficial when the desired mechanical characteristics cannot be achieved using either the elongated flexures or flexible circuits alone.

What is claimed is:

1. A printed circuit assembly comprising:
a printed circuit board;
a micro-electro-mechanical system on the printed circuit board; and
at least one motion damping member positioned between the printed circuit board and the micro-electro-mechanical system.

2. The printed circuit assembly of claim 1, wherein the at least one motion damping member comprises a flexible circuit.

3. The printed circuit assembly of claim 2, further comprising a cavity in the printed circuit board, wherein the micro-electro-mechanical system is supported within the cavity by the flexible circuit.

4. The printed circuit assembly of claim 3, further comprising a mechanically-dissipative material extending between the printed circuit board and the micro-electro-mechanical system.

5. A printed circuit assembly comprising:
a printed circuit board having a cavity therein; and
at least one micro-electro-mechanical system resiliently supported within the cavity.

6. The printed circuit assembly of claim 5, further comprising at least one flexible circuit resiliently supporting the at least one micro-electro-mechanical system within the cavity.

7. The printed circuit assembly of claim 5, further comprising an electrical connection between the at least one micro-electro-mechanical system and the printed circuit board.

8. The printed circuit assembly of claim 6, wherein the at least one flexible circuit is buckled.

9. The printed circuit assembly of claim 5, further comprising a mechanically-dissipative material extending between the at least one micro-electro-mechanical system and the printed circuit board.

10. A process for mounting a micro-electro-mechanical system to a printed circuit board, comprising resiliently supporting the micro-electro-mechanical system in a cavity on the printed circuit board

11. The process of claim 10, wherein resiliently supporting the micro-electro-mechanical system comprises resiliently supporting the micro-electro-mechanical system with a flexible circuit.

12. The process of claim 11, further comprising buckling the flexible circuit.

13. The process of claim 10, further comprising filling at least part of the cavity on the printed circuit board with a mechanically-dissipative material.

14. A printed circuit board assembly, comprising:
a printed circuit board;
a micro-electro-mechanical system; and
a vibration damping suspension operatively coupled between the micro-electro-mechanical system and the printed circuit board.

15. The printed circuit board assembly of claim 14, wherein the vibration damping suspension is a flexible circuit.

16. The printed circuit board assembly of claim 15, wherein the flexible circuit is buckled.

17. A process for mounting a micro-electro-mechanical system on a printed circuit board, comprising interposing a vibration damping suspension between a micro-electro-mechanical system and the printed circuit.

18. The process of claim 17, wherein interposing a vibration damping suspension comprises providing a flexible circuit between the micro-electro-mechanical system and the printed circuit.

19. The process of claim 18, further comprising buckling the flexible circuit.

20. A printed circuit board, comprising a mounting portion for connecting the printed circuit to an external support, a body for mounting electronic components, and at least one flexure extending between the mounting portion and the body of the printed circuit board.

21. The printed circuit board of claim 20, wherein the body, at least one flexure and mounting portion are a monolithic structure.

22. The printed circuit board of claim 20, wherein the at least one flexure comprises a first leg and a second leg disposed substantially perpendicular to one another.

23. The printed circuit board of claim 21, wherein the printed circuit board comprises a plurality of mounting portions disposed about the body, each of the plurality of mounting portions having at least one flexure extending to the body.

24. The printed circuit board of claim 20, further comprising a mechanically-dissipative material coupled between the at least one flexure and at least one of the body and the mounting portion.

25. A printed circuit board assembly comprising:
a printed circuit board;
a micro-electro-mechanical system supported on the printed circuit board; and
a plurality of vibration damping flexures extending from the printed circuit board to a mounting portion.

26. The printed circuit board assembly of claim 25, wherein the plurality of vibration damping flexures are positioned about a periphery of the printed circuit board.

27. The printed circuit board assembly of claim 25, further comprising a mechanically-dissipative material coupled between the vibration damping flexures and the printed circuit board.

28. The printed circuit board assembly of claim 25, further comprising a flexible circuit supporting the micro-electro-mechanical system on the printed circuit board.

29. A printed circuit assembly comprising:
a printed circuit board;
a micro-electro-mechanical system mounted on the printed circuit board; and
a plurality of slots extending into the printed circuit board from edges of the printed circuit board, wherein pairs of the plurality of slots are positioned to define mounting portions and flexures therebetween.

30. The printed circuit assembly of claim 29, wherein the pairs of the plurality of slots define mounting portions and flexures therebetween adjacent each corner of the printed circuit board.

31. The printed circuit assembly of claim 29, wherein the flexures defined by the pairs of slots each comprise a first leg and a second leg.

32. The printed circuit assembly of claim 31, wherein the first leg is substantially perpendicular to the second leg.

33. The printed circuit assembly of claim 29, further comprising a mechanically-dissipative material in the plurality of slots.

34. A printed circuit assembly comprising:
a printed circuit board;
a micro-electro-mechanical system supported on the printed circuit board; and
means for reducing the amount of external mechanical excitation transmitted to the micro-electro-mechanical system.

35. The printed circuit assembly of claim 34, wherein the means for reducing the amount of external mechanical excitation transmitted to the micro-electro-mechanical system comprises a flexible member coupled between a mounting portion of the printed circuit board and the micro-electro-mechanical system.

36. The printed circuit assembly of claim 35, wherein the flexible member comprises at least one flexible circuit supporting the micro-electro-mechanical system on the printed circuit board.

37. The printed circuit assembly of claim 35, wherein the flexible member comprises at least one flexure extending between a mounting portion and the printed circuit board.
